(19) United States
(12) Patent Application Publication
(10) Pub. No.: US 2008/0166661 A1
(43) Pub. Date: Jul. 10, 2008

(54) Method for forming a fine pattern in a semiconductor

(75) Inventor: Jae Chang Jung, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/804,674

(22) Filed: May 18, 2007

(30) Foreign Application Priority Data
Jan. 5, 2007 (KR) 10-2007-0001405

(51) Int. Cl. H01L 21/02; G03C 1/04; G03C 5/00

(52) U.S. Cl. 430/283.1; 430/285.1; 430/312

(57) ABSTRACT

A method for forming a fine pattern in a semiconductor device includes the steps of: coating a first photoresist composition over a semiconductor substrate including an underlying layer, thereby forming a first photoresist film; exposing and developing the first photoresist film, thereby forming a first photoresist pattern; forming a second photoresist film that does not react with the first photoresist pattern over the resulting structure; and exposing and developing the second photoresist film, thereby forming a second photoresist pattern; wherein the first and second photoresist patterns each comprise a plurality of elements, and individual elements of the second photoresist pattern are located between adjacent individual elements of the first photoresist pattern.

### CROSS-REFERENCE TO RELATED APPLICATION

Priority to Korean patent application number 10-2007-0001405, filed on Jan. 5, 2007, the disclosure of which is incorporated by reference in its entirety, is claimed.

### BACKGROUND OF THE INVENTION

The invention relates generally to a method for forming a fine pattern in a semiconductor device.

In order to manufacture smaller semiconductor devices, patterns have also become smaller. Research has been directed to developing resists and exposers for obtaining fine patterns.

Regarding exposers, KrF (248 nm) and ArF (193 nm) have been applied as an exposure light source, and attempts have been made to use short wavelength light sources such as F₂ (157 nm) or EUV (13 nm; extreme ultraviolet light) or to increase numerical apertures (NA).

However, when new light sources such as F₂ are applied, a new exposer is required, and increased manufacturing costs result. Also, the increase of numerical apertures degrades the focus depth width.

Although an immersion lithography process with an immersion solution having a high refractive index has been developed, it is difficult to apply the process on a mass production scale.

Meanwhile, a fine pattern having a resolution beyond the lithography limit has been formed by a double exposure method. However, it is difficult to secure margins of overlapping and arrangement, which results in excessive production cost and time.

### SUMMARY OF THE INVENTION

Various embodiments of the invention are directed at providing a method for forming a fine pattern which includes forming a second photoresist film over a first photoresist pattern already formed using a solubility difference, and then forming a second photoresist pattern, thereby having a pitch finer than the lithography limit.

According to an embodiment of the invention, a method for forming a fine pattern in a semiconductor device includes the steps of: coating a first photoresist composition over a semiconductor substrate including an underlying layer, thereby forming a first photoresist film; exposing and developing the first photoresist film, thereby forming a first photoresist pattern; forming a second photoresist film that does not react with the first photoresist pattern over the resulting structure; and exposing and developing the second photoresist film, thereby forming a second photoresist pattern; wherein the first and second photoresist patterns each comprise a plurality of elements, and individual elements of the second photoresist pattern are located between adjacent individual elements of the first photoresist pattern.

The first photoresist composition preferably includes: an addition copolymer having a repeating unit derived from a (meth)acrylic ester having an acid labile protecting group, a repeating unit derived from a (meth)acrylic ester having a hydroxyl group, and a repeating unit derived from acrylamide; a photoacid generator; and an organic solvent. The polymer preferably includes a 2-methyl-2-adamantyl methacrylate repeating unit, a 2-hydroxyethyl methacrylate repeating unit and an N-isopropyl acrylamide repeating unit.

The first photoresist composition preferably includes a polymer in an amount ranging from 5 to 20 weight parts; a photoacid generator in an amount ranging from 0.05 to 1 weight parts; and an organic solvent, all based on 100 weight parts of the composition.

The step of coating the first photoresist composition preferably includes baking the first photoresist composition at a temperature ranging from 90° C. to 150° C. for 30 seconds to 180 seconds.

The step of exposing and developing the first photoresist film preferably includes exposing the first photoresist film with a first exposure mask having a line pattern with a specified pitch by an exposure energy ranging from 10 mJ/cm² to 200 mJ/cm²; post-baking the resulting structure at a temperature ranging from 90° C. to 150° C. for 30 seconds to 180 seconds; and developing the resulting structure.

The step of exposing and developing the second photoresist film preferably includes exposing the second photoresist film with a second exposure mask having a line pattern with a specified pitch by an exposure energy ranging from 10 mJ/cm² to 200 mJ/cm²; post-baking the resulting structure at a temperature ranging from 90° C. to 150° C. for 30 seconds to 180 seconds; and developing the resulting structure.

The second exposure mask is preferably the first exposure displaced a specified distance, or it can be an additional exposure mask.

Exposure of the first and second photoresist pattern films preferably includes using immersion lithography equipment.

The first and second photoresist patterns each have a specified pitch. The first and second photoresist patterns together define a composite photoresist pattern and the composite photoresist pattern has a composite pitch equal to half of the specified pitch.

### BRIEF DESCRIPTION OF THE DRAWINGS

FIGS. 1a through 1c are cross-sectional diagrams illustrating a method for forming a fine pattern in a semiconductor device according to an embodiment of the invention.

FIG. 2 is an NMR spectrum of the first photoresist polymer of Example 1.

FIG. 3 is an SEM photograph of the fine pattern of Example 3.

### DETAILED DESCRIPTION OF THE SPECIFIC EMBODIMENT

Exemplary specific embodiments of invention is described in detail with reference to the accompanying drawings.

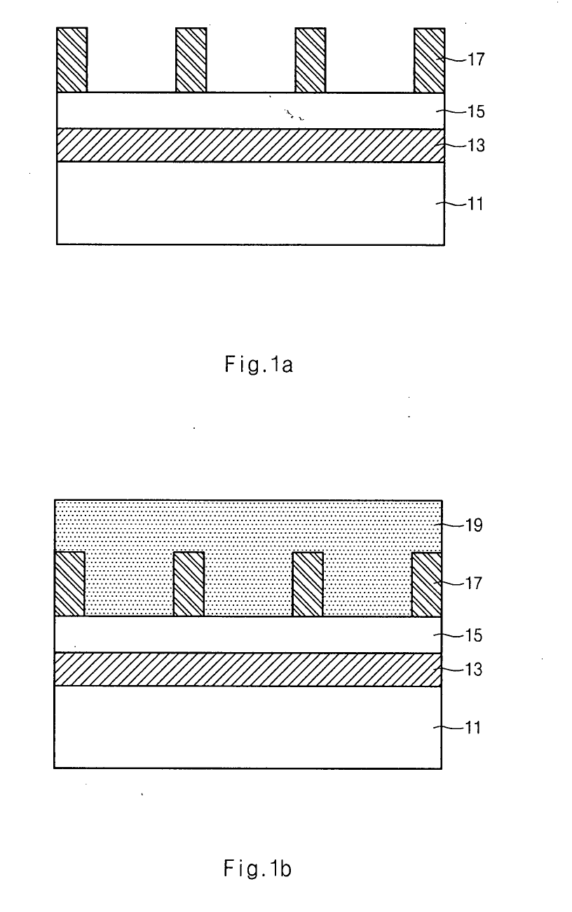

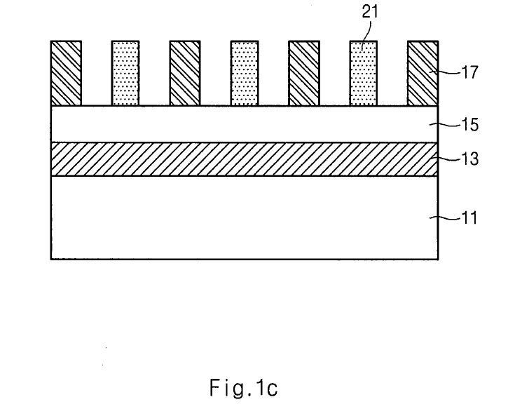

FIGS. 1a through 1c are cross-sectional diagrams illustrating a method for forming a fine pattern in a semiconductor device according to an embodiment of the invention.

A hard mask layer 13 is formed over a semiconductor substrate 11 having an underlying layer which includes a given lower structure. An anti-reflection film 15 is formed over the hard mask layer 13.

A first photoresist composition is coated over the anti-reflection film 15, and then baked at a temperature ranging from 90° C. to 150° C. for 30 seconds to 180 seconds to form a first photoresist film (not shown).

The first photoresist composition includes an addition copolymer having a repeating unit derived from a (meth)acrylic ester having an acid labile protecting group, a repeating unit derived from a (meth)acrylic ester having a hydroxyl group and a repeating unit derived from acrylamide (including alkyl substituted forms thereof); a photoacid generator; and an organic solvent.

The polymer is present in an amount ranging from 5 to 20 weight parts, based on 100 weight parts of the first photoresist composition. The photoresist film becomes excessively thin when the polymer amount is less than 5 weight parts, and the photoresist film becomes excessively thick when the polymer amount is over 20 weight parts.

The photoacid generator is present in an amount ranging from 0.05 to 1 weight part, based on 100 weight parts of the first photoresist composition. The photoacid generator is preferably one or more selected from the group consisting of triphenyl sulfonium nonafluorobutanesulfonate, diphenyliodide hexafluorophosphate, diphenyliodide hexafluoroarsenate, diphenyliodide hexafluoroantimonate, diphenyl p-methoxyphenyl triflate, diphenyl p-toluenyl triflate, diphenyl p-isobutylphenyl triflate, triphenylsulfonium hexafluoroarsenate, triphenylsulfonium hexfluoroantimonate, triphenylsulfonium triflate, triphenylsulfonium trifluoromethansulfonate dibutylnaphtylsulfonium triflate, and mixtures thereof.

The organic solvent is preferably selected from the group consisting of methyl 3-methoxypropionate, ethyl 3-ethoxypropinate, propyleneglycol methyletheracetate, cyclohexanone, 2-heptanone, n-butanol, n-pentanol, ethyl lactate, and mixtures thereof.

The first photoresist composition may further include an organic base. The organic base lessens the effect of basic compounds (e.g., an amine) present in the air on patterns obtained after an exposure process, and further regulates the shape of patterns.

The organic base is preferably selected from the group consisting of triethylamine, triisobutylamine, triisooctylamine, triisodecylamine, diethanolamine, triethanolamine, and mixtures thereof.

The first photoresist film is preferably exposed with a first exposure mask having a line pattern of pitch A by an exposure energy ranging from 10 mJ/cm² to 200 mJ/cm² using immersion lithography equipment. The light source of the exposure process is selected from the group consisting of G-line (436 nm), i-line (365 nm), KrF (248 nm), ArF (193 nm), F₂ (157 nm) and EUV (13 nm).

The resulting structure is post-baked at a temperature ranging from 90° C. to 150° C. for 30 seconds to 180 seconds, and developed with a 2.38 wt % tetramethyl ammonium hydroxide (TMAH) aqueous solution to form a first photoresist pattern 17.

A second photoresist composition is coated over the resulting structure to form a second photoresist film 19.

Any suitable chemically amplified photoresist composition can be used in the immersion lithography process as the second photoresist composition. The second photoresist composition does not dissolve the first photoresist pattern 17; thus, the shape of the first photoresist pattern 17 is not changed even when the second photoresist composition is coated.

The second photoresist film 19 is exposed with a second exposure mask having a line pattern of pitch A by an exposure energy ranging from 10 mJ/cm² to 200 mJ/cm² using immersion lithography equipment. The light source of the exposure process is preferably selected from the group consisting of G-line (436 nm), i-line (365 nm), KrF (248 nm), ArF (193 nm), F₂ (157 nm) and EUV (13 nm).

The second exposure mask is preferably the first exposure mask displaced a specified distance, or it can be an additional exposure mask.

The resulting structure is post-baked at a temperature ranging from 90° C. to 150° C. for 30 seconds to 180 seconds, and developed with a 2.38 wt % TMAH aqueous solution to form a second photoresist pattern 21 having individual elements between adjacent individual elements of the first photoresist pattern 17. Both the first and second photoresist patterns 17, 21 have a pitch A that is the minimum size limit of the lithography process. The staggered arrangement of the first and second photoresist patterns 17, 21 results in a composite photoresist pattern having a reduced pitch A/2 (i.e., a pitch smaller than the lithography limit).

When the second photoresist pattern 21 is formed, the first photoresist pattern 17 is not developed in the exposure and developing process, even when the first photoresist pattern 17 receives light.

According to another embodiment of the invention, the method steps represented by FIGS. 1a through 1c are repeated at least two or more times, thereby obtaining an even finer pattern.

### EXAMPLE 1

### Preparation of a First Photoresist Polymer

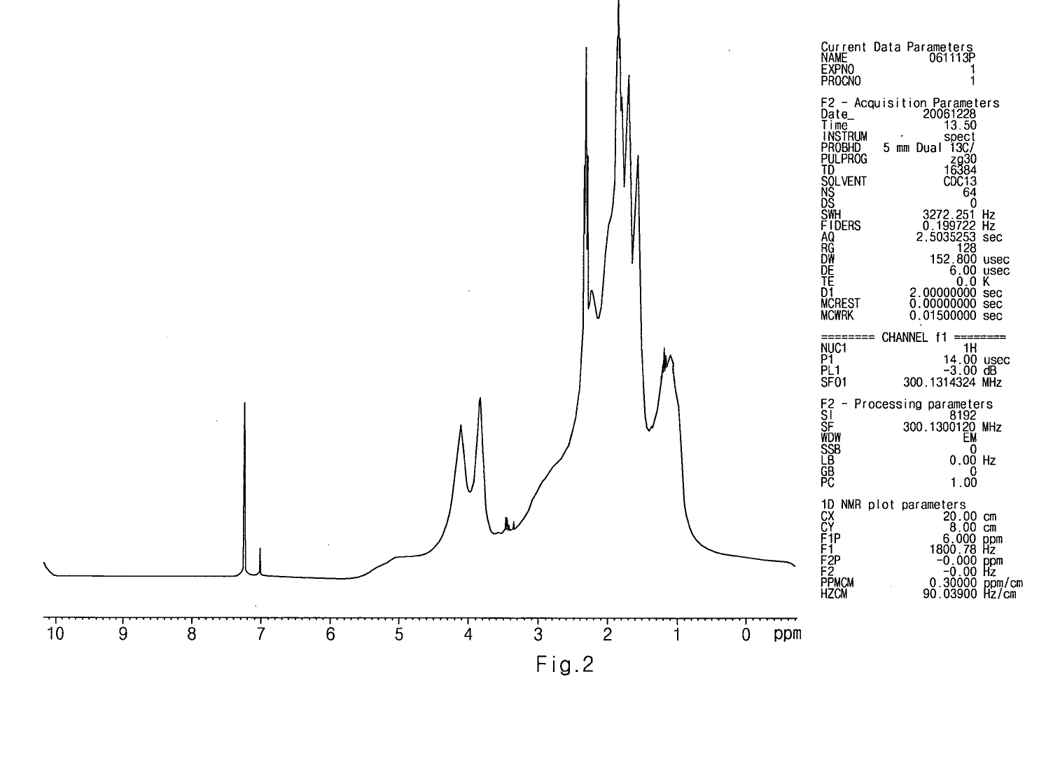

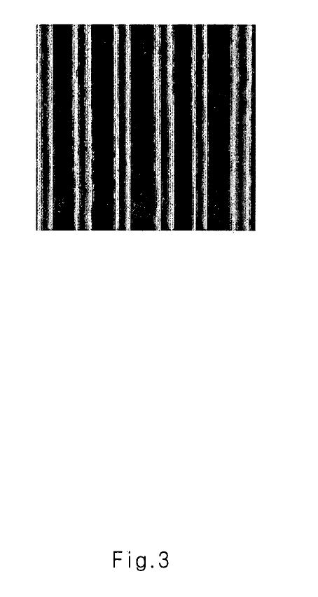

To a round flask (250 mL) were added 2-methyl-2-adamantyl methacrylate (12 g), 2-hydroxyethyl methacrylate (8 g), N-isopropyl acrylamide (1 g), azobisisobutyronitrile (AIBN) (0.6 g) as a polymerization initiator and propylenegylcol methyl ether acetate (PGMEA) (100 g). The resulting mixture was reacted under a nitrogen atmosphere for 8 hours. After reaction, the resulting polymer was precipitated in diethyl ether (1000 mL) and dehydrated in a vacuum to obtain a first photoresist polymer according to the invention (yield: 89%). FIG. 2 is an NMR spectrum of the resulting polymer.

### EXAMPLE 2

### Preparation of a First Photoresist Composition

In cyclohexanone (170 g) were dissolved the first photoresist polymer (10 g) obtained from Example 1, triphenylsulfonium nonafluorobutane sulfonate (0.4 g) and triethanolamine (0.006 g) to obtain a first photoresist composition according to the invention.

### EXAMPLE 3

### Formation of a Fine Pattern

Formation of a first photoresist pattern

The first photoresist composition obtained from Example 2 was coated over a wafer, and pre-baked at 100° C. for 60 seconds to form a first photoresist film. The first photoresist film was exposed with a mask having an 80 nm half pitch by an exposure energy of 35 mJ/cm² using immersion lithography equipment. The resulting structure was post-baked at 100° C. for 60 seconds, and developed with a 2.38 wt % TMAH aqueous solution, thereby obtaining a 40 nm first photoresist pattern.

Formation of a second photoresist pattern

An AIM5076 photoresist composition (produced by JSR Co.) was coated over the above resulting structure, and pre-baked at 100° C. for 60 seconds to form a second photoresist film. The second photoresist film was exposed with a mask having an 80 nm half pitch by an exposure energy of 38 mJ/cm² using immersion lithography equipment. The resulting structure was post-baked at 100° C. for 60 seconds, and developed with a 2.38 wt % TMAH aqueous solution, thereby obtaining a 40 nm second photoresist pattern.

Since the elements of the second photoresist pattern were formed between adjacent elements of the first photoresist pattern, the resulting composite pattern was formed to have a 40 nm half pitch with a mask having a 80 nm half pitch (see FIG. 3). The mask used in the second exposure process was the same mask used in the first exposure process, although it was shifted a specified distance in between the two exposure processes

As described above, in a method for forming a fine pattern in a semiconductor device according to an embodiment of the invention, a second photoresist composition is coated over a first photoresist pattern that does not react with the second photoresist composition. As a result, elements of the second photoresist pattern are formed between elements of the first photoresist patterns, thereby obtaining a fine composite pattern having a pitch finer than the lithography limit. Furthermore, the above method can be repeated several times to obtain an even finer pattern.

The above embodiments of the invention are illustrative and not limiting. Various alternatives and equivalents are possible. The invention is not limited by the lithography steps described herein, nor is the invention limited to any specific type of semiconductor device. For example, the invention may be implemented in a dynamic random access memory (DRAM) device or a non-volatile memory device. Other additions, subtractions, or modifications that are obvious in view of the present disclosure and are intended to fall within the scope of the appended claims.

What is claimed is:

1. A method for forming a fine pattern in a semiconductor device, the method comprising the steps of:
coating a first photoresist composition over a semiconductor substrate including an underlying layer, thereby forming a first photoresist film;
exposing and developing the first photoresist film, thereby forming a first photoresist pattern;
forming a second photoresist film that does not react with the first photoresist pattern over the resulting structure; and
exposing and developing the second photoresist film, thereby forming a second photoresist pattern;
wherein:
the first and second photoresist patterns each comprise a plurality of elements; and
individual elements of the second photoresist pattern are located between adjacent individual elements of the first photoresist pattern.

2. The method according to claim 1, wherein the first photoresist composition comprises: an addition co polymer comprising a repeating unit derived from a (meth)acrylic ester having an acid labile protecting group, a repeating unit derived from a (meth)acrylic ester having a hydroxyl group and a repeating unit derived from acrylamide; a photoacid generator; and an organic solvent.

3. The method according to claim 2, wherein the copolymer comprises a 2-methyl-2-adamantyl methacrylate repeating unit, a 2-hydroxyethyl methacrylate repeating unit, and an N-isopropyl acrylamide repeating unit.

4. The method according to claim 2, wherein the first photoresist composition further comprises an organic base.

5. The method according to claim 4, wherein the organic base is selected from the group consisting of triethylamine, triisobutylamine, triisooctylamine, triisodecylamine, diethanolamine, triethanolamine, and mixtures thereof.

6. The method according to claim 1, wherein the first photoresist composition comprises the addition copolymer in an amount ranging from 5 to 20 weight parts; a photoacid generator in an amount ranging from 0.05 to 1 weight parts; and an organic solvent, wherein the amounts are based on 100 weight parts of the composition.

7. The method according to claim 1, wherein the step of coating the first photoresist composition comprises baking the first photoresist composition at a temperature ranging from 90° C. to 150° C. for 30 seconds to 180 seconds.

8. The method according to claim 1, wherein the step of exposing and developing the first photoresist film comprises:
exposing the first photoresist film with a first exposure mask having a line pattern with a specified pitch by an exposure energy ranging from 10 mJ/cm² to 200 mJ/cm²;
post-baking the resulting structure at a temperature ranging from 90° C. to 150° C. for 30 seconds to 180 seconds; and
developing the resulting structure.

9. The method according to claim 8, wherein the step of exposing and developing the second photoresist film comprises:
exposing the second photoresist film with a second exposure mask having a line pattern with a specified pitch by an exposure energy ranging from 10 mJ/cm² to 200 mJ/cm²;
post-baking the resulting structure at a temperature ranging from 90 to 150° C. for 30 seconds to 180 seconds; and
developing the resulting structure.

10. The method according to claim 9, wherein the second exposure mask is the first exposure mask displaced a specified distance.

11. The method according to claim 9, wherein the second exposure make is different from the first exposure mask.

12. The method according to claim 1, wherein the step of exposing the first photoresist film comprises using immersion lithography equipment.

13. The method according to claim 1, wherein the step of exposing the second photoresist film comprises using immersion lithography equipment.

14. The method according to claim 1, wherein:
the first and second photoresist patterns each have a specified pitch;
the first and second photoresist patterns together define a composite photoresist pattern; and
the composite photoresist pattern has a composite pitch equal to half of the specified pitch.

15. A photoresist composition comprising: an addition copolymer comprising a repeating unit derived from a (meth)acrylic ester having an acid labile protecting group, a repeating unit derived from a (meth)acrylic ester having a hydroxyl group, and a repeating unit derived from acrylamide; a photoacid generator; and an organic solvent.

16. The photoresist composition according to claim 15, wherein the polymer comprises a 2-methyl-2-adamantyl methacrylate repeating unit, 2-hydroxyethyl methacrylate repeating unit, and an N-isopropyl acrylamide repeating unit.

17. The photoresist composition according to claim 15, further comprising an organic base.

18. The photoresist composition according to claim 17, wherein the organic base is selected from the group consisting of triethylamine, triisobutylamine, triisooctylamine, triisodecylamine, diethanolamine triethanolamine, and mixtures thereof.
